(19) United States
(12) Patent Application Publication
(10) Pub. No.: US 2022/0122915 A1
(43) Pub. Date: Apr. 21, 2022

(54) SEMICONDUCTOR STRUCTURE AND FABRICATION METHOD THEREOF

(71) Applicant: UNITED MICROELECTRONICS CORP., Hsin-Chu City (TW)

(72) Inventors: Yen-Tsai Yi, Tainan City (TW); Wei-Chuan Tsai, Changhua County (TW); Jin-Yan Chiou, Tainan City (TW); Hsiang-Wen Ke, Kaohsiung City (TW)

(21) Appl. No.: 17/073,413

(22) Filed: Oct. 19, 2020

(51) Int. Cl. H01L 23/535; H01L 23/522; H01L 23/532; H01L 21/321; H01L 21/768

(52) U.S. Cl. CPC H01L 23/535; H01L 23/5226; H01L 23/53228; H01L 23/53261; H01L 23/53266; H01L 21/76895; H01L 21/76805; H01L 21/76834; H01L 21/7684; H01L 21/76846; H01L 21/76877; H01L 21/3212

(57) ABSTRACT

A semiconductor structure includes a substrate; a first inter-layer dielectric (ILD) layer on the substrate; an etch stop layer on the first ILD layer; a second inter-layer dielectric (ILD) layer on the etch stop layer; and a copper damascene interconnect layer disposed in the first ILD layer. A tungsten via structure is disposed in the second ILD layer and the etch stop layer, and is electrically connected to the copper damascene interconnect layer. The tungsten via structure includes a tungsten layer and a barrier layer surrounding the tungsten layer. An intermetallic layer is disposed between the barrier layer and the copper damascene interconnect layer.

### BACKGROUND OF THE INVENTION

### 1. Field of the Invention

The present invention relates to the field of semiconductor technology, and in particular to an improved method of manufacturing a semiconductor structure with improved adhesion.

### 2. Description of the Prior Art

As known in the art, magnetic random-access memory (MRAM) devices are typically processed using structures upon which are formed a plurality of magnetic metal stacks which comprise the magnetic memory cells. A magnetic stack comprises many different layers of metals and a thin layer of dielectric having a total thickness of a few tens of nanometers. The magnetic stacks are typically built on top of a tungsten via on a copper wire embedded in an inter-level dielectric (ILD) material.

However, the bonding strength between the tungsten via and the underlying copper wire is weak, which leads to tungsten via missing issue during a chemical mechanical polishing (CMP) process. Therefore, there is a need in this industry to provide a semiconductor structure with improved adhesion between the tungsten via and the underlying copper wire to cope with the tungsten via missing issue.

### SUMMARY OF THE INVENTION

One object of the present invention is to provide an improved method of manufacturing a semiconductor structure to solve the above-mentioned shortcomings and shortcomings of the prior art.

One aspect of the invention provides a semiconductor structure includes a substrate; a first inter-layer dielectric (ILD) layer on the substrate; an etch stop layer on the first ILD layer; a second inter-layer dielectric (ILD) layer on the etch stop layer; and a copper damascene interconnect layer disposed in the first ILD layer. A tungsten via structure is disposed in the second ILD layer and the etch stop layer, and is electrically connected to the copper damascene interconnect layer. The tungsten via structure includes a tungsten layer and a barrier layer surrounding the tungsten layer. An intermetallic layer is disposed between the barrier layer and the copper damascene interconnect layer.

According to some embodiments, the barrier layer comprises tantalum (Ta), tantalum (TaN), titanium (Ti), titanium nitride (TiN), titanium silicon nitride (TiSiN), titanium tungsten (TiW), tungsten nitride (WN), ruthenium (Ru), rhodium (Rh), hafnium (Hf), iridium (Ir), niobium (Nb), molybdenum (Mo), rhenium (Re), ruthenium (Ru), osmium (Os), cobalt (Co), manganese (Mn), or palladium (Pd).

According to some embodiments, the barrier layer comprises a titanium layer and a titanium nitride layer, and wherein the intermetallic layer comprises a copper-titanium alloy layer.

According to some embodiments, the titanium layer has a vertical portion around a sidewall of the tungsten layer and a horizontal portion under the tungsten layer, wherein the vertical portion has a first thickness that is greater than a second thickness of the horizontal portion.

According to some embodiments, the first thickness is about 80-90 angstroms and the second thickness is about 10-60 angstroms.

According to some embodiments, the copper-titanium alloy layer is in direct contact with the titanium layer and the copper damascene interconnect layer.

According to some embodiments, the copper-titanium alloy layer has a thickness of about 30-70 angstroms.

According to some embodiments, the etch stop layer comprises a nitrogen-doped carbide (NDC) layer.

According to some embodiments, the first ILD layer comprises an ultra-low dielectric constant (ULK) layer and the second ILD layer comprises a tetraethylorthosilicate (TEOS) oxide layer.

According to some embodiments, the copper damascene interconnect layer comprises a cobalt capping layer or a manganese capping layer.

Another aspect of the invention provides a method for forming a semiconductor structure. A substrate having a first inter-layer dielectric (ILD) layer is provided. A copper damascene interconnect layer is formed in the first ILD layer. An etch stop layer is formed on the first ILD layer and the copper damascene interconnect layer. A second inter-layer dielectric (ILD) layer is formed on the etch stop layer. A via opening is formed in the second ILD layer and the etch stop layer to at least partially expose a top surface of the copper damascene interconnect layer. A barrier layer is formed on an interior surface of the via opening and on the top surface of the copper damascene interconnect layer. An anneal process is performed to form an intermetallic layer between the barrier layer and the copper damascene interconnect layer. The via opening is filled with a tungsten layer.

According to some embodiments, after filling the via opening with the tungsten layer, the method further comprises: subjecting the tungsten layer and the barrier layer to a chemical mechanical polishing (CMP) process to remove the tungsten layer and the barrier layer from the second ILD layer.

According to some embodiments, the anneal process is performed by using a rapid thermal process.

According to some embodiments, the anneal process is performed in-situ in a CVD chamber after the barrier layer is deposited.

According to some embodiments, the barrier layer comprises a titanium layer and a titanium nitride layer.

According to some embodiments, the intermetallic layer comprises a copper-titanium alloy layer.

According to some embodiments, the titanium layer has a vertical portion around a sidewall of the tungsten layer and a horizontal portion under the tungsten layer, wherein the vertical portion has a first thickness that is greater than a second thickness of the horizontal portion.

According to some embodiments, the first thickness is about 80-90 angstroms and the second thickness is about 10-60 angstroms.

According to some embodiments, the copper-titanium alloy layer is in direct contact with the titanium layer and the copper damascene interconnect layer.

According to some embodiments, the copper-titanium alloy layer has a thickness of about 30-70 angstroms.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic, cross-sectional diagrams showing an exemplary method for forming a semiconductor structure according to one embodiment of the invention.

FIG. 6 is a schematic, cross-sectional diagram showing a semiconductor structure according to another embodiment of the invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized and structural, logical, and electrical changes may be made without departing from the scope of the present invention. Therefore, the following detailed description is not to be considered as limiting, but the embodiments included herein are defined by the scope of the accompanying claims.

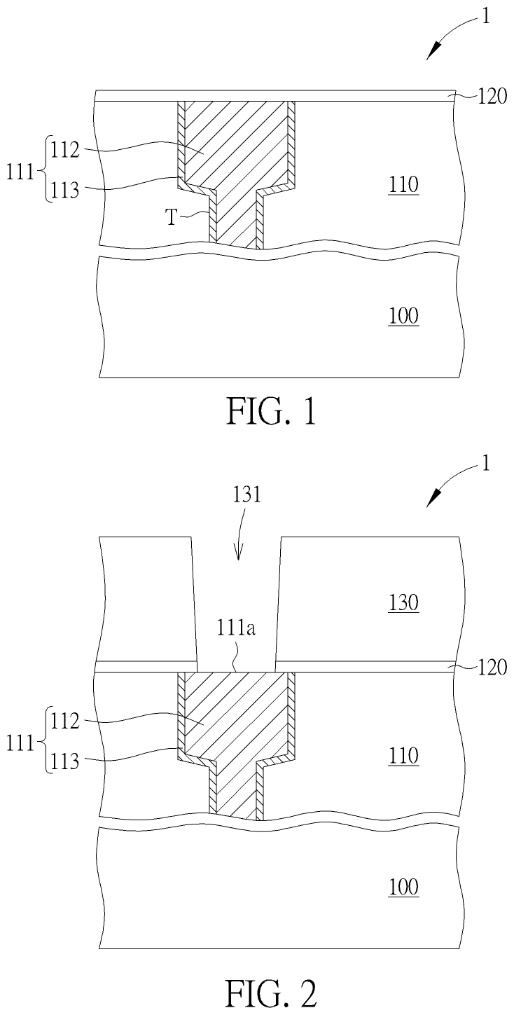

Please refer to FIG. 1 to FIG. 5. FIG. 1 to FIG. 5 are schematic, cross-sectional diagrams showing an exemplary method for forming a semiconductor structure 1 according to one embodiment of the invention. As shown in FIG. 1, a substrate 100 is provided. According to an embodiment, the substrate 100 may be a semiconductor substrate such as a silicon substrate, but is not limited thereto. A first inter-layer dielectric (ILD) layer 110 is deposited on the substrate 100. According to an embodiment, for example, the first ILD layer 110 may be an ultra-low k (ULK) dielectric layer. According to an embodiment, for example, the ULK dielectric layer may have a dielectric constant k smaller than 2.8, but not limited thereto.

A copper damascene interconnect layer 111 is formed in the first ILD layer 110. For example, to form the copper damascene interconnect layer 111, a trench T is formed in the first ILD layer 110 first. A diffusion barrier layer 113 such as a titanium (Ti) layer and a titanium nitride (TiN) layer is then conformally deposited into the trench T. A copper layer 112 is then deposited on the diffusion barrier layer 113 to fill the trench T. The copper layer 112 and the diffusion barrier layer 113 are then subjected to a chemical mechanical polishing (CMP) process. The copper layer 112 and the diffusion barrier layer 113 outside the trench T are removed. An etch stop layer 120 such as a silicon nitride layer or a nitrogen-doped carbide (NDC) layer is then formed on the first ILD layer 110 and the copper damascene interconnect layer 111.

As shown in FIG. 2, subsequently, a second inter-layer dielectric (ILD) layer 130 is deposited on the etch stop layer 120. According to an embodiment, for example, the second ILD layer 130 may be a silicon oxide layer such as a tetraethylorthosilicate (TEOS) oxide layer, but not limited thereto. A via opening 131 is then formed in the second ILD layer 130 and the etch stop layer 120. According to an embodiment, the via opening 131 at least partially exposes a top surface 111a of the copper damascene interconnect layer 111.

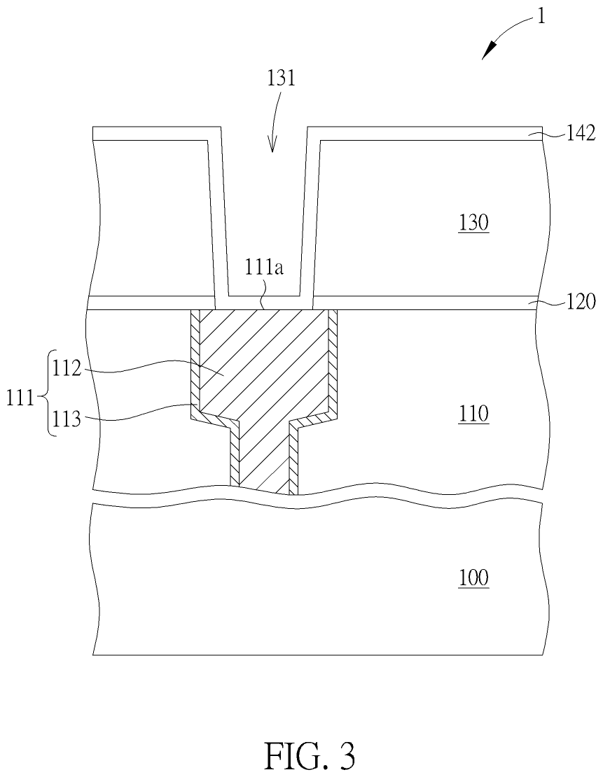

As shown in FIG. 3, a barrier layer 140 is formed on an interior surface of the via opening 131 and on the top surface 111a of the copper damascene interconnect layer 111. According to an embodiment, for example, the barrier layer 140 may comprise tantalum (Ta), tantalum (TaN), titanium (Ti), titanium nitride (TiN), titanium silicon nitride (TiSiN), titanium tungsten (TiW), tungsten nitride (WN), ruthenium (Ru), rhodium (Rh), hafnium (Hf), iridium (Ir), niobium (Nb), molybdenum (Mo), rhenium (Re), ruthenium (Ru), osmium (Os), cobalt (Co), manganese (Mn), or palladium (Pd).

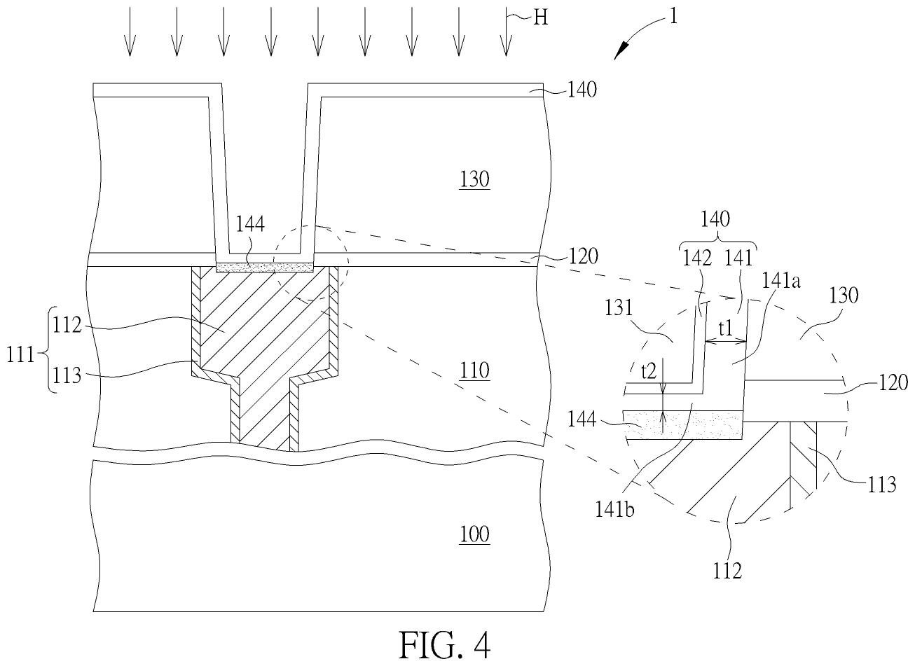

As shown in FIG. 4, an anneal process H is then performed to form an intermetallic layer 144 between the barrier layer 142 and the copper damascene interconnect layer 111. According to an embodiment, for example, the anneal process H may be performed by using a rapid thermal process. According to an embodiment, for example, the barrier layer 140 comprises a titanium layer 141 and a titanium nitride layer 142. According to an embodiment, the intermetallic layer 144 comprises a copper-titanium alloy layer. According to an embodiment, for example, the titanium layer 141 may be formed by using a physical vapor deposition (PVD) method.

According to an embodiment, for example, the titanium nitride layer 142 may be formed by using a chemical vapor deposition (CVD) method. According to an embodiment, for example, the anneal process H may be performed in-situ in a CVD chamber after the titanium nitride layer 142 is deposited. Therefore, the aforesaid mentioned rapid thermal process may be skipped.

According to an embodiment, for example, the anneal process H may be performed at a temperature that is higher than 400 degrees Celsius, but not limited thereto. According to an embodiment, for example, the anneal process H may be performed at a temperature ranging between about 350 and 500 degrees Celsius. According to an embodiment, for example, the duration of the anneal process H may be about 2 minutes, but is not limited thereto.

According to an embodiment, as depicted in the enlarged view in FIG. 4, the titanium layer 141 has a vertical portion 141a and a horizontal portion 141b. The vertical portion 141a has a first thickness t₁ that is greater than a second thickness t₂ of the horizontal portion 141b. According to an embodiment, for example, the first thickness t₁ is about 80-90 angstroms and the second thickness t₂ is about 10-60 angstroms. According to an embodiment, for example, the copper-titanium alloy layer 144 is in direct contact with the titanium layer 141 and the copper damascene interconnect layer 111. According to an embodiment, for example, the copper-titanium alloy layer 144 may have a thickness of about 30-70 angstroms. The copper-titanium alloy layer 144 increases the bonding strength between the barrier layer 140 and the copper damascene interconnect layer 111.

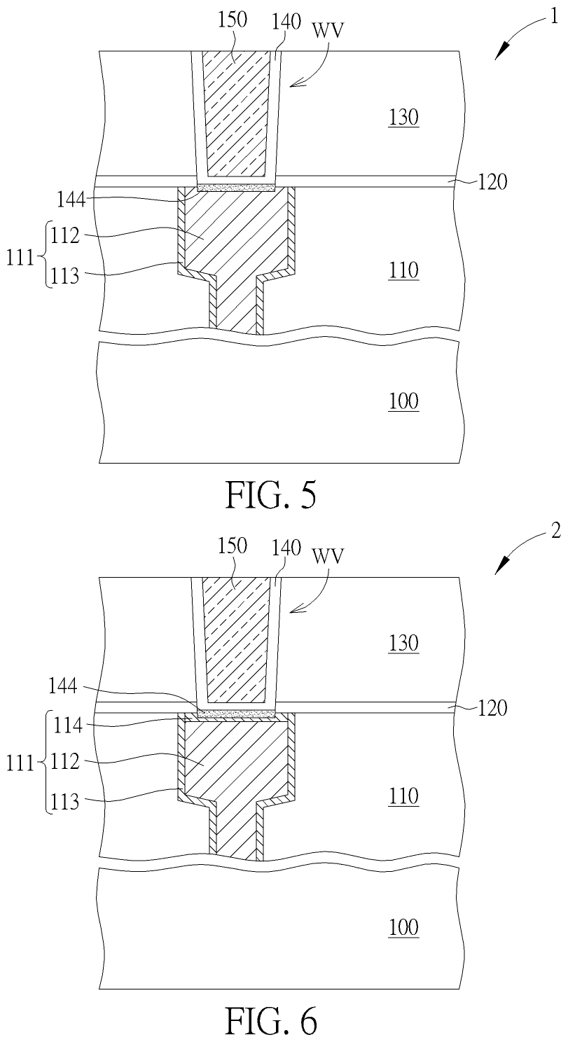

As shown in FIG. 5, after the anneal process H is performed and the copper-titanium alloy layer 144 is formed on the copper damascene interconnect layer 111, a tungsten layer 150 is then deposited to fill via opening 131. After filling the via opening 131 with the tungsten layer 150, the tungsten layer 150 and the barrier layer 140 are subjected to a CMP process to remove the tungsten layer 150 and the barrier layer 140 from the second ILD layer 130, thereby forming a tungsten via structure WV.

Structurally, as shown in FIG. 4 and FIG. 5, the semiconductor structure 1 includes a substrate 100, a first ILD layer 110 on the substrate 100, an etch stop layer 120 on the first ILD layer 110, a second ILD layer 130 on the etch stop layer 120, and a copper damascene interconnect layer 111 disposed in the first ILD layer 110. A tungsten via structure WV is disposed in the second ILD layer 130 and the etch stop layer 120. The tungsten via structure WV is electrically connected to the copper damascene interconnect layer 111. The tungsten via structure WV includes a tungsten layer 150 and a barrier layer 140 surrounding the tungsten layer 150. An intermetallic layer 144 is disposed between the barrier layer 140 and the copper damascene interconnect layer 111.

According to some embodiments, the barrier layer comprises tantalum (Ta), tantalum (TaN), titanium (Ti), titanium nitride (TiN), titanium silicon nitride (TiSiN), titanium tungsten (TiW), tungsten nitride (WN), ruthenium (Ru), rhodium (Rh), hafnium (Hf), iridium (Ir), niobium (Nb), molybdenum (Mo), rhenium (Re), ruthenium (Ru), osmium (Os), cobalt (Co), manganese (Mn), or palladium (Pd).

According to some embodiments, the barrier layer 140 may comprise a titanium layer 141 and a titanium nitride layer 142, and the intermetallic layer 144 may comprise a copper-titanium alloy layer. According to some embodiments, the titanium layer 141 has a vertical portion 141a around a sidewall of the tungsten layer 150 and a horizontal portion 141b under the tungsten layer 150. The vertical portion 141a has a first thickness t₁ that is greater than a second thickness t₂ of the horizontal portion 141b.

According to some embodiments, the first thickness t₁ is about 80-90 angstroms and the second thickness t₂ is about 10-60 angstroms.

According to some embodiments, the copper-titanium alloy layer 144 is in direct contact with the titanium layer 141 and the copper damascene interconnect layer 111. According to some embodiments, the copper-titanium alloy layer 144 has a thickness of about 30-70 angstroms.

FIG. 6 is a schematic, cross-sectional diagram showing a semiconductor structure 2 according to another embodiment of the invention. As shown in FIG. 6, the difference between the semiconductor structure 1 in FIG. 5 and the semiconductor structure 2 in FIG. 6 is that the copper damascene interconnect layer 111 of the semiconductor structure 2 in FIG. 6 comprises a capping layer 114 on the copper layer 112. According to some embodiments, the capping layer 114 may be a cobalt capping layer or a manganese capping layer. According to some embodiments, the intermetallic layer 144 may comprise metal alloys having a composition expressed by a general formula AₓB₍₁₋ₓ₎ or metal alloys having a composition expressed by a general formula AₓB_{y}C_{z}. A is at least one selected from the group consisting of tantalum (Ta), tantalum (TaN), titanium (Ti), titanium nitride (TiN), titanium silicon nitride (TiSiN), titanium tungsten (TiW), tungsten nitride (WN), ruthenium (Ru), rhodium (Rh), hafnium (Hf), iridium (Ir), niobium (Nb), molybdenum (Mo), rhenium (Re), ruthenium (Ru), osmium (Os), cobalt (Co), manganese (Mn), or palladium (Pd). B is at least one selected from the group consisting of copper (Cu), tungsten (W) or aluminum (Al). C is at least one selected from the group consisting of cobalt (Co) or manganese (Mn). The value of x, y, and z may be ranged from 0% to 100%.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate;
a first inter-layer dielectric (ILD) layer on the substrate;
an etch stop layer on the first ILD layer;
a second inter-layer dielectric (ILD) layer on the etch stop layer;
a copper damascene interconnect layer disposed in the first ILD layer;
a tungsten via structure disposed in the second ILD layer and the etch stop layer, and being electrically connected to the copper damascene interconnect layer, wherein the tungsten via structure comprises a tungsten layer and a barrier layer surrounding the tungsten layer; and
an intermetallic layer disposed between the barrier layer and the copper damascene interconnect layer.

2. The semiconductor structure according to claim 1, wherein the barrier layer comprises tantalum, tantalum, titanium, titanium nitride, titanium silicon nitride, titanium tungsten, tungsten nitride, ruthenium, rhodium, hafnium, iridium, niobium, molybdenum, rhenium, ruthenium, osmium, cobalt, manganese, or palladium.

3. The semiconductor structure according to claim 2, wherein the barrier layer comprises a titanium layer and a titanium nitride layer, and wherein the intermetallic layer comprises a copper-titanium alloy layer.

4. The semiconductor structure according to claim 3, wherein the titanium layer has a vertical portion around a sidewall of the tungsten layer and a horizontal portion under the tungsten layer, wherein the vertical portion has a first thickness that is greater than a second thickness of the horizontal portion.

5. The semiconductor structure according to claim 4, wherein the first thickness is about 80-90 angstroms and the second thickness is about 10-60 angstroms.

6. The semiconductor structure according to claim 3, wherein the copper-titanium alloy layer is in direct contact with the titanium layer and the copper damascene interconnect layer.

7. The semiconductor structure according to claim 6, wherein the copper-titanium alloy layer has a thickness of about 30-70 angstroms.

8. The semiconductor structure according to claim 1, wherein the etch stop layer comprises a nitrogen-doped carbide (NDC) layer.

9. The semiconductor structure according to claim 1, wherein the first ILD layer comprises an ultra-low dielectric constant (ULK) layer and the second ILD layer comprises a tetraethylorthosilicate (TEOS) oxide layer.

10. The semiconductor structure according to claim 1 wherein the copper damascene interconnect layer comprises a cobalt capping layer or a manganese capping layer.

11. A method for forming a semiconductor structure, comprising:
providing a substrate having a first inter-layer dielectric (ILD) layer;
forming a copper damascene interconnect layer in the first ILD layer;
forming an etch stop layer on the first ILD layer and the copper damascene interconnect layer;
forming a second inter-layer dielectric (ILD) layer on the etch stop layer;
forming a via opening in the second ILD layer and the etch stop layer to at least partially expose a top surface of the copper damascene interconnect layer;
forming a barrier layer on an interior surface of the via opening and on the top surface of the copper damascene interconnect layer;
performing an anneal process to form an intermetallic layer between the barrier layer and the copper damascene interconnect layer; and
filling the via opening with a tungsten layer.

12. The method according to claim 11, wherein after filling the via opening with the tungsten layer, the method further comprises:
subjecting the tungsten layer and the barrier layer to a chemical mechanical polishing (CMP) process to remove the tungsten layer and the barrier layer from the second ILD layer.

13. The method according to claim 11, wherein the anneal process is performed by using a rapid thermal process.

14. The method according to claim 11, wherein the anneal process is performed in-situ in a CVD chamber after the barrier layer is deposited.

15. The method according to claim 11, wherein the barrier layer comprises a titanium layer and a titanium nitride layer.

16. The method according to claim 15, wherein the intermetallic layer comprises a copper-titanium alloy layer.

17. The method according to claim 16, wherein the titanium layer has a vertical portion around a sidewall of the tungsten layer and a horizontal portion under the tungsten layer, wherein the vertical portion has a first thickness that is greater than a second thickness of the horizontal portion.

18. The method according to claim 17, wherein the first thickness is about 80-90 angstroms and the second thickness is about 10-60 angstroms.

19. The method according to claim 16, wherein the copper-titanium alloy layer is in direct contact with the titanium layer and the copper damascene interconnect layer.

20. The method according to claim 19, wherein the copper-titanium alloy layer has a thickness of about 30-70 angstroms.
